(19) United States
(12) Patent Application Publication
(10) Pub. No.: US 2010/0044868 A1
(43) Pub. Date: Feb. 25, 2010

(54) SEMICONDUCTOR DEVICE

(76) Inventors: Hiroshi NASU, Osaka (JP); Minoru Fujisaku, Kyoto (JP); Michinari Tetani, Osaka (JP); Hyoe Ueda, Yamagata (JP); Hisashi Takahashi, Osaka (JP)

Correspondence Address: MCDERMOTT WILL & EMERY LLP, 600 13TH STREET, NW, WASHINGTON, DC, 20005-3096, US

(21) Appl. No.: 12/477,601

(22) Filed: Jun. 3, 2009

(30) Foreign Application Priority Data
Aug. 25, 2008 (JP) 2008-215329

(51) Int. Cl. H01L 23/522

(52) U.S. Cl. 257/758; 257/E23.142

(57) ABSTRACT

A semiconductor device includes an external terminal, a plurality of first interconnections, an electrode, a conductor, and a second interconnection. The first interconnections are positioned below the external terminal. The electrode is positioned at the same level as the first interconnections and is electrically connected to the external terminal through the conductor. The second interconnection is positioned below the first interconnections and the electrode. The semiconductor device has a region where the shortest distance between an edge surface of the electrode and an edge surface of one of the first interconnections positioned most adjacent to the electrode is less than 0.11 times the total thickness of the conductor and the electrode. The second interconnection is positioned at a position different from that of the region in a thickness direction of the semiconductor device.

### CROSS-REFERENCE TO RELATED APPLICATION

This application claims priority from Japanese Patent Application No. JP2008-215329 filed on Aug. 25, 2008, which is hereby incorporated by reference in its entirety for all purposes.

### BACKGROUND

The present disclosure relates to a semiconductor device.

Recently, there has been a need for miniaturization and advanced function of electronic devices. To meet this need, semiconductor devices (semiconductor packages) formed by a packaging process have been required to have a small-sized and high-density structure. The requirement for high density has led to a need for providing products with multiple terminals. Various types of chip-scale packages (CSPs) have been developed as small-sized semiconductor packages with multiple terminals.

Particular attention has been recently drawn to a wafer-level CSP (WLCSP; wafer-level chip scale package) as a technology that achieves a package whose size is extremely small similar to a bare chip. A wafer-level CSP is generally fabricated according to the following method. First, an insulating resin film is formed over the entire surface of a semiconductor wafer in which a plurality of integrated circuits are formed; then, interconnections are formed on the insulating resin film (these interconnections electrically connect pad electrodes of the integrated circuits and external terminals through a penetrating conductor); and the semiconductor wafer is divided in the final step.

Semiconductor packages having inductor elements therein have recently been released, too. An inductor element was originally a different part from a semiconductor chip and so-called an outside part of a semiconductor device. In these semiconductor packages, the inductor elements are formed on the insulating resin film with the use of interconnections to be connected to external terminals.

Furthermore, there have also been semiconductor packages not only having inductor elements but also having capacitor elements or shielding plates therein (that block noise effect from conductors). In these semiconductor packages, interconnections to be connected to external terminals have a multi-layered structure, and are densely positioned with smaller pitches. This enables these semiconductor packages to have advanced functions and excellent performance. A semiconductor device of WLCSP type into which these functions are added is expected as an ultra small semiconductor package applicable to a device using a frequency of several hundred MHz to several GHz (for example, a mobile device or a local area network).

A structure of a conventional semiconductor device will be described with reference to FIGS. 8 and 9. FIG. 8 illustrates a cross-sectional view showing an example of a conventional semiconductor device, and FIG. 9 illustrates a cross-sectional view showing a condition where a conventional WLCSP is mounted on a mounting substrate.

The conventional semiconductor device includes semiconductor elements such as, for example, a MOS (Metal Oxide Semiconductor) transistor, a diode transistor or bipolar transistor formed by a PN junction in an upper surface of a semiconductor substrate 7. These semiconductor elements are electrically insulated from the outside world and protected from the outside atmosphere by a surface passivation film 5.

A lower interconnection (hereinafter referred to as “a third interconnection”) 6 and an Al interconnection pad 8 are positioned on the semiconductor substrate 7. An external terminal 13 is connected to the Al interconnection pad 8 through a middle interconnection (hereinafter referred to as “a second interconnection”) 10, an electrode 1 and a conductor 14. This makes it possible to take out signals from the Al interconnection pad 8 to the outside world of the semiconductor device. The electrode 1 and the external terminal 13 are connected to each other through the conductor 14, thereby improving reliability in packaging the semiconductor device. A sealing resin 2 protects the electrode 1, the conductor 14, and upper interconnections (hereinafter referred to as “first interconnections”) 15, which makes it possible to protect the electrode 1, the conductor 14, and the first interconnections 15 from an impact or an atmosphere outside the semiconductor device. The external terminal 13 is, for example, a solder bump that is electrically connected to the mounting substrate.

The electrode 1, the first interconnections 15 and the second interconnection 10 are insulated by a first insulating film 3, and the second interconnection 10, the third interconnection 6 and the Al interconnection pad 8 are insulated by a second insulating film 4. The electrode 1, the first interconnections 15 and the second interconnection 10 are formed by an electrolytic plating process. Therefore, a metal layer 11 is formed under the electrode 1 and the first interconnections 15, and a metal layer 9 is formed under the second interconnection 10.

A method for mounting the semiconductor device on a mounting substrate 21 will be described below. First, a WLCSP 19 is positioned on a mounting substrate 21 with the WLCSP 19 having a solder bump 20 on a lower surface thereof, so that the solder bump 20 is positioned on a terminal 22 of the mounting substrate 21, as shown in FIG. 9. Then, a heat treatment process (220 to 260° C.) is implemented. This allows the solder bump 20 to melt and to be connected to the terminal 22 of the mounting substrate 21.

Note that, for example, Japanese Laid-Open Patent Publication No. 2008-21789 describes the WLCSP in which the second interconnection is formed above the Al interconnection pad; the electrode and the first interconnections are formed above the second interconnection; and the conductor is formed on the electrode.

### SUMMARY

It is necessary for a conventional WLCSP to reduce pitches of interconnections smaller to position the interconnections densely in order to accomplish advanced functions and excellent performance in the conventional WLCSP. Therefore, while there is a region in which the distance between an electrode and interconnections (first interconnections) positioned at the same level as the electrode is narrow, in some cases, another interconnection (a second interconnection or a third interconnection) is positioned directly under the region. In this case, a metal layer to be used for forming the electrode and the first interconnections by an electrolytic plating process might not be etched so as to have a desired shape. In other words, part of the metal layer might remain between the electrode and one of the first interconnections positioned most adjacent to the electrode. Therefore, there has been a problem that a short-circuit fault occurs. The reason why the short-circuit fault occurs will be described below with reference to FIGS. 10 and 11.

FIG. 10A illustrates a plan view for showing a condition after a metal layer 11 is etched in the conventional WLCSP, and FIG. 10B illustrates its cross-sectional view. FIG. 11A illustrates a perspective view of FIG. 10B, viewed from an X direction, and FIG. 11B illustrates a perspective view of FIG. 10B, viewed from a Y direction.

As a method for etching the metal layer 11, a wet etching method is adopted from a cost standpoint.

As shown in FIGS. 10A and 10B, when the metal layer 11 is etched, part of the metal layer 11 existing between an electrode 1 and one of first interconnections 15 tends to be affected by a thickness (a) of a conductor 14 and the thickness (b) of the electrode 1. Thus, the part of the metal layer 11 existing in a region between the electrode 1 and one of the first interconnections 15 positioned most adjacent to the electrode 1 is likely to be hided behind the conductor 14 during the etching of the metal layer 11. Therefore, an etching solution is less likely to go through the region between the electrode 1 and one of the first interconnections 15 positioned most adjacent to the electrode 1.

Furthermore, the following failure occurs when the distance (c) or (c′) between the electrode 1 and one of the first interconnections 15 positioned most adjacent to the electrode 1 is narrow and at least one of the second interconnection 10 and the third interconnection 6 is formed directly under the region between the electrode 1 and one of the first interconnections 15 positioned most adjacent to the electrode 1. As shown in FIGS. 11A and 11B, part of the metal layer 11 is rising, affected by the second interconnection 10, the third interconnection 6, or both of the second interconnection 10 and the third interconnection 6. The etching solution flows along an arrow 25 shown in FIGS. 11A and 11B. Therefore, the etching solution does not sufficiently go through a region 24 in FIGS. 11A and 14B and as a result, part of the metal layer 11 remains in the region 24 without being etched.

A semiconductor device according to the present invention includes an external terminal, a plurality of first interconnections, an electrode, a conductor, and a second interconnection. The first interconnections are positioned below the external terminal and at the same level as the electrode. The conductor electrically connects the external terminal and the electrode. The second interconnection is positioned below the first interconnections and the electrode. This semiconductor device has a region where the shortest distance between an edge surface of the electrode and an edge surface of one of the first interconnections positioned most adjacent to the electrode is less than 0.11 times a total thickness of the conductor and the electrode. The second interconnection is positioned at a position different from that of the region in a thickness direction of the device.

This semiconductor device can prevent a short-circuit fault from occurring even when the first interconnections and the electrode are formed by an electrolytic plating process.

Preferred embodiments described below include multiple ones of the external terminals, the conductors, the electrodes, and the regions. The one external terminal is connected to the one electrode through the one conductor. The second interconnection is positioned at a position different from those of all the regions in the thickness direction of the device.

The semiconductor device according to the present invention may include a third interconnection positioned below the second interconnection. In this case, the third interconnection is preferably positioned at a position different from that of the region in a thickness direction of the device. This can more sufficiently prevent a short failure from occurring even when the first interconnections and the electrode are formed by electrolytic plating process.

When the semiconductor device includes the third interconnection, the device may include multiple ones of the external terminals, the conductors, the electrodes, and the regions. The one electrode is connected to the one external terminal through the one conductor. The second interconnection is preferably positioned at a position different from those of all the regions in the thickness direction of the device.

In preferred embodiments to be described hereinafter, each of the first and the second interconnections include Cu and has a thickness of 1.5 μm or more. Further, the third interconnection includes Al and has a thickness of 1.5 μm or more.

### BRIEF DESCRIPTION OF THE DRAWINGS

FIG. 1 illustrates a cross-sectional view of a semiconductor device according to an embodiment of the invention.

FIG. 2 illustrates a flowchart showing a method of fabricating a semiconductor device according to one embodiment of the invention.

FIG. 3A illustrates a plan view showing a condition immediately after a metal layer 11 is etched in the semiconductor device according to one embodiment of the invention.

FIG. 3B illustrates a cross-sectional view showing the condition immediately after the metal layer 11 is etched in the semiconductor device according to one embodiment of the invention.

FIG. 4 illustrates a perspective view of FIG. 3B, viewed from an X direction or a Y direction.

FIG. 5 illustrates a graph showing the relationship between a resistance R and a ratio (d).

FIG. 6 illustrates a plan view of a semiconductor device according to Modified Example 1.

FIG. 7 illustrates a plan view of a semiconductor device according to Modified Example 2.

FIG. 8 illustrates a cross-sectional view showing an example of a conventional semiconductor device.

FIG. 9 illustrates a cross-sectional view showing a condition where a conventional WLCSP is mounted on a mounting substrate.

FIG. 10A illustrates a plan view showing a condition after a metal layer is etched in the conventional WLCSP.

FIG. 10B illustrates a cross-sectional view showing the condition after the metal layer is etched in the conventional WLCSP.

FIG. 11A illustrates a perspective view of FIG. 10B, viewed from an X direction.

FIG. 11B illustrates a perspective view of FIG. 10B, viewed from a Y direction.

### DETAILED DESCRIPTION OF PREFERRED EMBODIMENTS

Hereinafter, embodiments of the present invention will be described with reference to the accompanying drawings. The present invention is not limited to these described embodiments.

### Embodiment

An embodiment describes a semiconductor device and a method for fabricating the semiconductor.

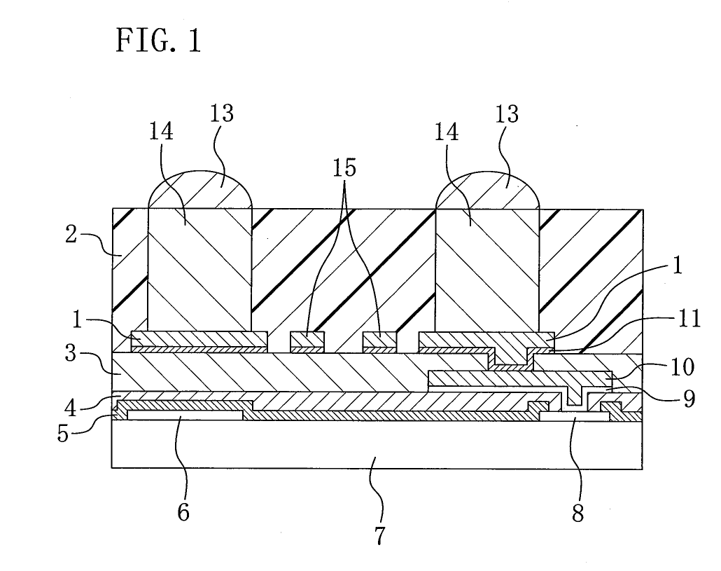

FIG. 1 illustrates a cross-sectional view of a semiconductor device according to one embodiment of the invention.

The semiconductor device according to one embodiment of the invention includes semiconductor elements, such as, for example, a MOS (Metal Oxide Semiconductor) transistor, a diode transistor or bipolar transistor formed by a PN junction in an upper surface of a semiconductor substrate 7. These semiconductor elements are electrically insulated from the outside world and protected from the outside atmosphere by a surface passivation film 5.

The semiconductor device according to one embodiment of the invention places a third interconnection 6 and an Al interconnection pad 8 on the semiconductor substrate 7. An external terminal 13 is connected to the Al interconnection pad 8 through the second interconnection 10, electrode 1 and conductor 14. This makes it possible to take out signals from the Al interconnection pad 8 to the outside world of the semiconductor device. The electrode 1 and the external terminal 13 are connected to each other through the conductor 14, thereby improving reliability in packaging the semiconductor device. A sealing resin 2 protects the electrode 1, the conductor 14, and a plurality of first interconnections 15, which makes it possible to protect the electrode 1, the conductor 14, and the first interconnections 15 from an impact or an atmosphere outside the semiconductor device. The external terminal 13 is, for example, a solder bump that is electrically connected to the mounting substrate.

The electrode 1, the first interconnections 15 and the second interconnection 10 are insulated by a first insulating film 3, and the second interconnection 10, the third interconnection 6 and the Al interconnection pad 8 are insulated by a second insulating film 4. The electrode 1, the first interconnections 15 and the second interconnection 10 are formed by an electrolytic plating process. Therefore, a metal layer 11 is formed under the electrode 11 and the first interconnections 15, and a metal layer 9 is formed under the second interconnection 10.

The metal layers 9 and 11 may have a multiple layer structure with various types of metals. In view of the case of forming an inductor element in the semiconductor device, it is preferable that the Al interconnection pad 8, the third interconnection 6, the second interconnection 10, and the first interconnections 15 respectively have a thickness of 1.5 μm or more.

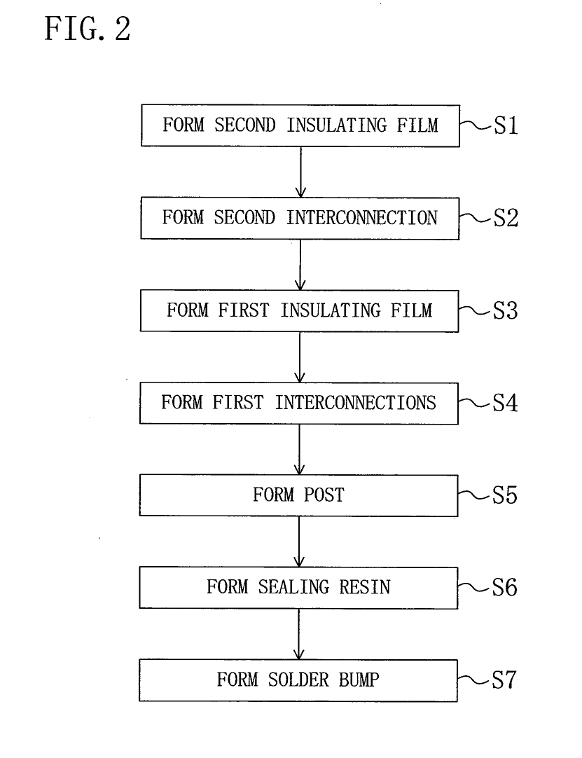

FIG. 2 illustrates a flowchart showing a method of fabricating a semiconductor device according to one embodiment of the invention.

The method of fabricating the semiconductor device according to one embodiment of the invention includes the following steps: after a step of setting in a predetermined device the semiconductor substrate 7 having semiconductor elements therein, S1 of forming the second insulating film 4; S2 of forming the second interconnection 10; S3 of forming the first insulating film 3; S4 of forming the first interconnections 15; S5 of forming a post (the conductor 14); S6 of forming the sealing resin 2; and S7 of forming the solder bump (the external terminal 13), as shown in FIG. 2. Not shown in FIG. 2, the method of fabricating the semiconductor device according to one embodiment of the invention also includes a photolithography process, a plating process, and an etching process as an interconnection pattering process for forming interconnection patterns. In a sub-step between the step of setting the semiconductor substrate 7 and the step S1, the surface passivation film 5 is formed after the third interconnection 6 and the Al interconnection pad 8 are formed. In the Step S4, the electrode 1 and the first interconnections 15 are simultaneously formed.

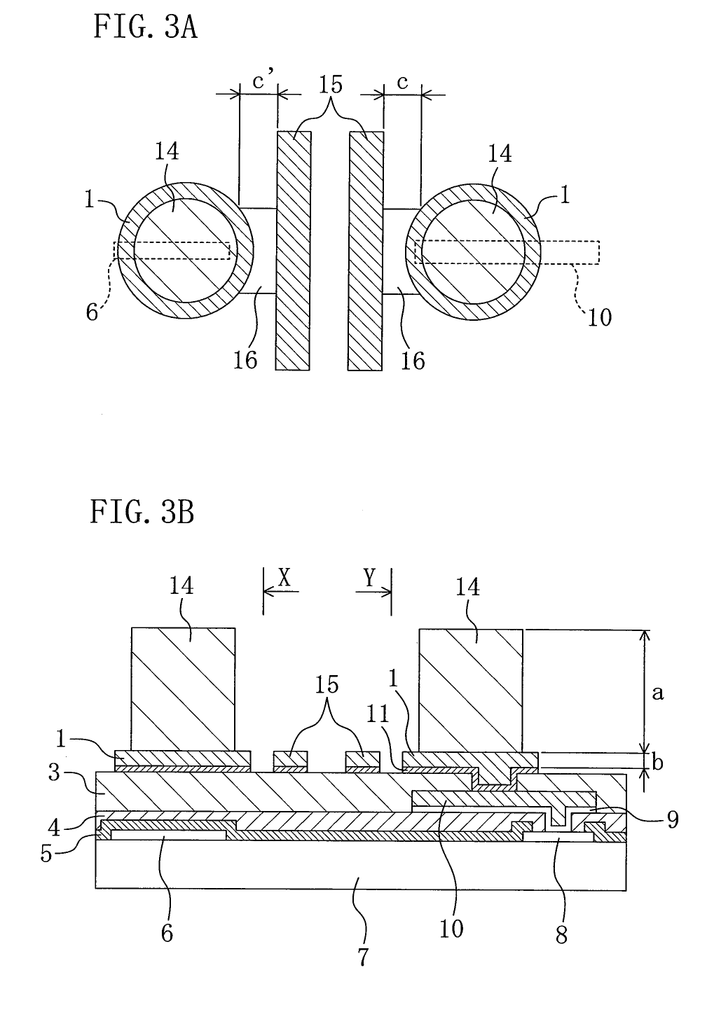

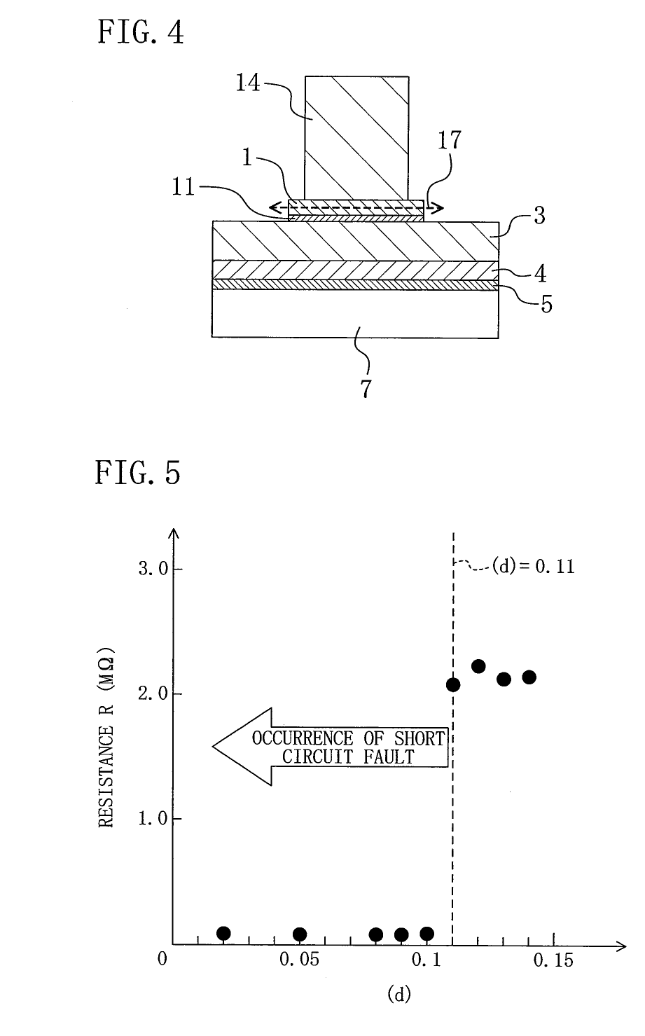

FIG. 3A illustrates a plan view showing a condition immediately after the metal layer 11 is etched in the semiconductor device of FIG. 1 and FIG. 3B illustrates its cross-sectional view. FIG. 4 illustrates a perspective view of FIG. 3B, viewed from an X direction or a Y direction.

As shown in FIGS. 3A and 3B, the semiconductor device according to one embodiment of the invention has a region 16. The region 16 is a region where the shortest distance (c) or (c′) between an edge surface of the electrode 1 and an edge surface of one of the first interconnections 15 positioned most adjacent to the electrode 1 is less than 0.11 times a total thickness of the conductor 14 (a) and the electrode 1 (b). The second interconnection 10 and the third interconnection 6 are not positioned directly under the region 16. In other words, the second interconnection 10 and the third interconnection 6 are positioned at a position different from that of the region 16 in a thickness direction of the device.

With the above structure, the metal layer 11 is not affected by the second interconnection 10 and the third interconnection 6 as shown in FIG. 4. Therefore, an etching solution flows along an arrow 17 in FIG. 4, and the metal layer 11 is etched without substantially leaving residues even in the region 16. This enables to suppress a short circuit between the electrode 1 and the first interconnections 15. Even when pitches of the first interconnections 15 are narrower so that the first interconnections 15 are densely positioned, a short circuit between the electrode 1 and the first interconnections 15 can be suppressed.

FIG. 5 illustrates a graph for showing the relationship between a resistance R and a ratio (d). The ratio (d) refers to a value obtained by dividing the shortest distance (c) or (c′) between the edge surface of the electrode 1 and the edge surface of one of the first interconnections 15 positioned most adjacent to the electrode 1 by the total thickness of the conductor 14 (a) and the electrode 1 (b). The resistance R refers to a resistance between the electrode 1 and one of the first interconnections 15 positioned most adjacent to the electrode 1. Note that a WLCSP used for the measurement of the values has the second interconnection 10 or the third interconnection 6 directly under the region 16.

As can be appreciated from the graph shown in FIG. 5, it can be seen that the resistance R and the ratio (d) definitely relate to each other. Specifically, when the ratio (d) is less than 0.11, the resistance R is measured so as to be recognized as causing a short-circuit fault. On the other hand, when the ratio (d) is 0.11 or more, it can be found that the resistance R has a high value, the short-circuit failure does not happen, and the metal film 11 is etched without substantially leaving residues in the region 16.

As explained above, one embodiment of the invention does not provide the second interconnection 10 and the third interconnection 6 directly under the region 16. In other words, one embodiment of the invention provides the second interconnection 10 and the third interconnection 6 at a position different from that of the region 16 in a thickness direction of the device. This enables to prevent the second interconnection 10 and the third interconnection 6 from rising in the region 16, thereby allowing a solution (etching solution) to efficiently flow through the region 16, and allowing the metal layer to be etched without substantially leaving residues in the region 16. This makes it possible to prevent a short-circuit fault from occurring in the region 16. As described above, the structure of one embodiment of the present invention can prevent the short-circuit failure from occurring in the region 16 even when each pitch of the first interconnections 15 is narrower.

Note that the second and the third interconnections may be positioned as explained hereinafter in Modified Example 1 and may be positioned as explained hereinafter in Modified Example 2.

### Modified Example 1

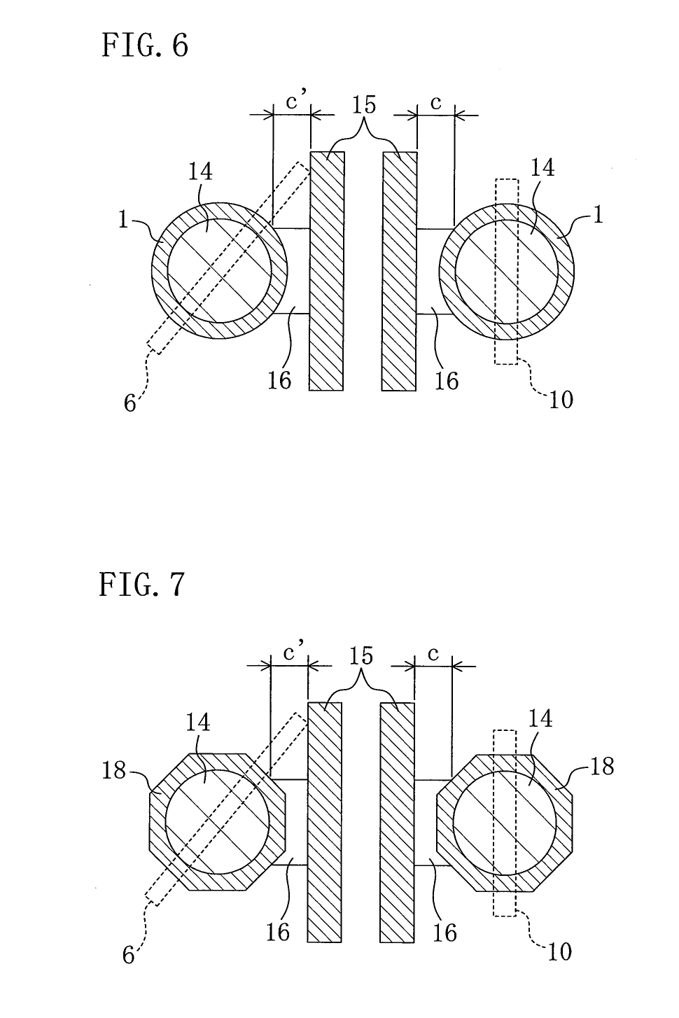

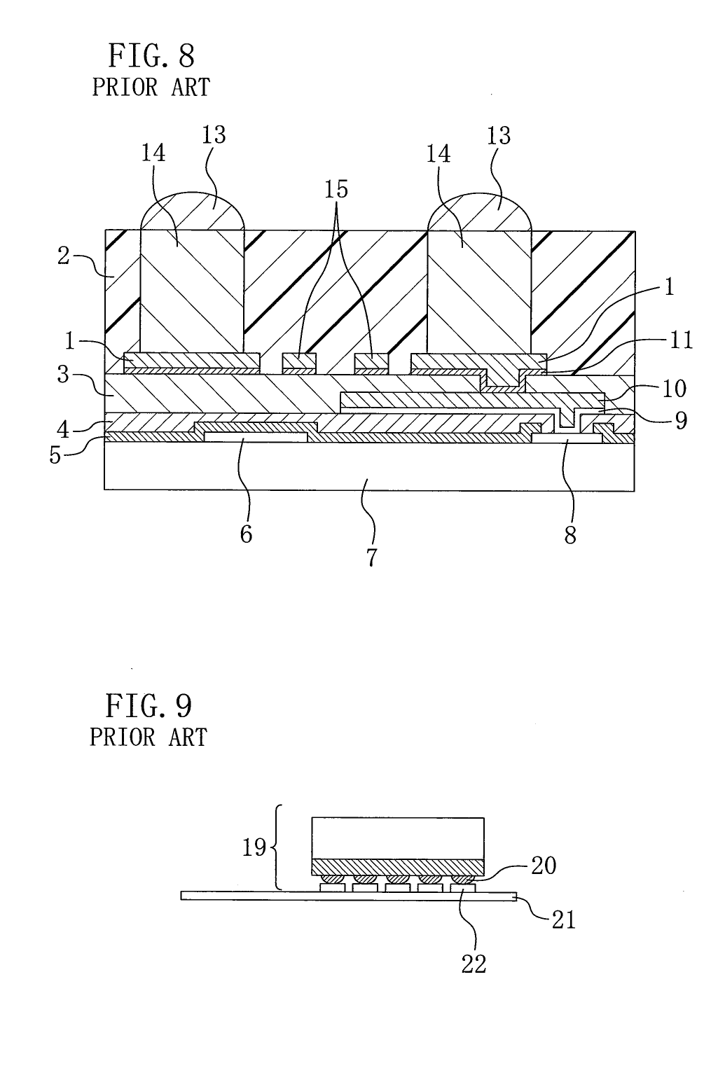

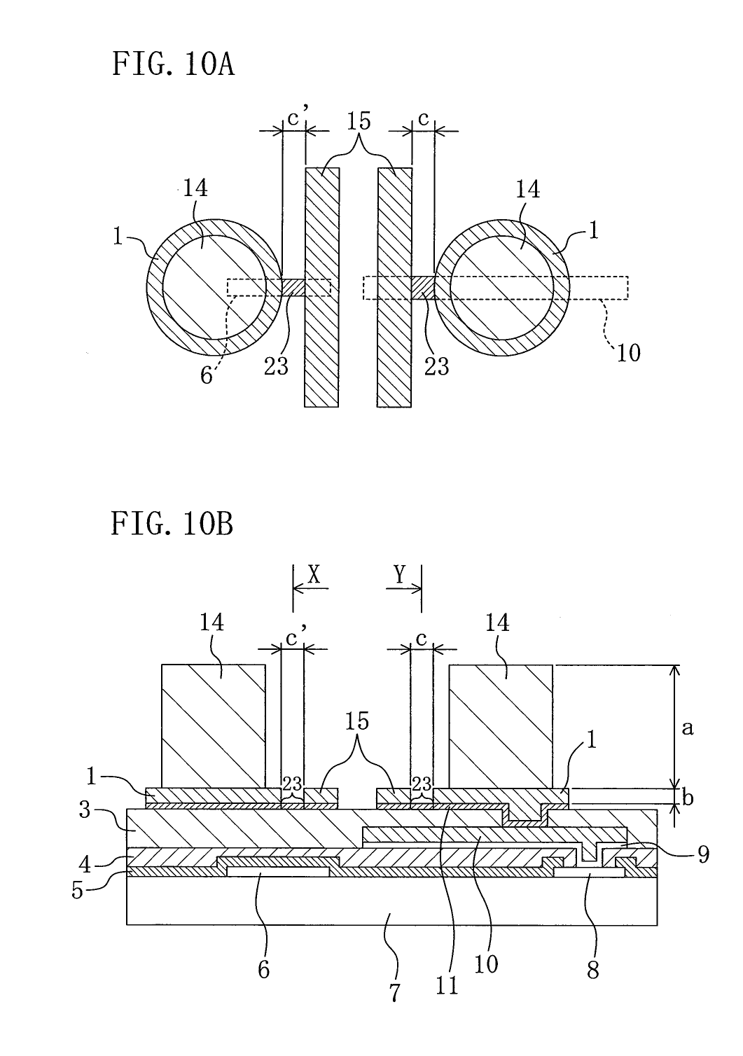

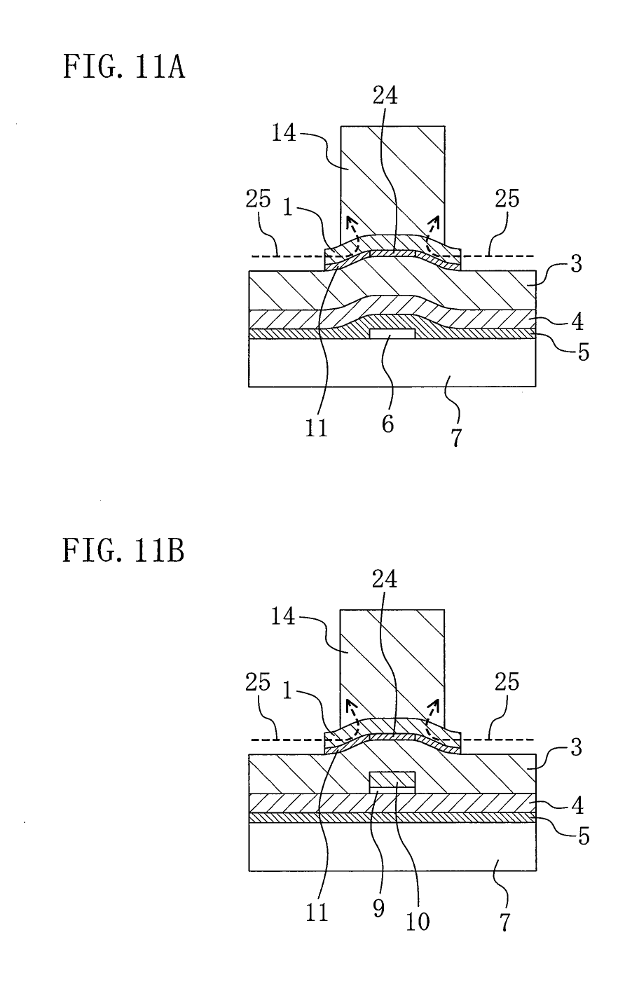

FIG. 6 illustrates a plan view of a semiconductor device according to Modified Example 1.

FIG. 6 illustrates that a longitudinal direction of the second interconnection 10 is parallel to that of the first interconnections 15, and a longitudinal direction of the third interconnection 6 is tilted relative to that of one of the first interconnections 15. In this way, unless the second interconnection 10 and the third interconnection 6 are positioned directly below the region 16, the metal layer 11 is etched without substantially leaving residues in the region 16, irrespective of how the second interconnection 10 and the third interconnection 6 are positioned. The present modified example is able to prevent the short-circuit fault from occurring in the region 16. Therefore, the short-circuit failure can be prevented in the region 16 even when the each pitch of the first interconnections 15 is narrower so that the first interconnections 15 are densely positioned.

### Modified Example 2

FIG. 7 illustrates a plan view of a semiconductor device according to Modified Embodiment 2.

In FIG. 7, an electrode 18 has an octagonal shape when viewed in plan. Even in this case, a short-circuit between the electrode 1 and the first interconnections 15 can be suppressed unless the second interconnection 10 and the third interconnection 6 are positioned directly below the region 16. This can ensure the similar effect as the aforementioned embodiment.

### Other Embodiments

The present invention may have a structure as hereinafter described.

A substrate material constituting the WLCSP in the invention is generally silicon but may be a semiconductor substrate that can form a semiconductor element (for example, GaAs or quartz). Even when using a semiconductor substrate formed from GaAs or quartz, the same effect as the aforementioned embodiment can be achieved as long as the second interconnection 10 and the third interconnection 6 are positioned at a position different from that of the region 16.

Any materials can be used as a material for the interconnections in the invention as long as they are electrically conductive materials. Preferably, the first and the second interconnections may include at least Cu and the third interconnection may include at least Al. Any materials can be used as an insulating material as long as they are electrically insulative materials. In any case, the same effect as the aforementioned embodiment can be secured only if the second interconnection 10 and the third interconnection 6 are positioned at a position different from that of the region 16 in a thickness direction of the device.

The present invention discloses the structure of the WLCSP including the first to the third interconnections but the number of interconnections is not limited. That is, the first metal layer is etched without leaving the residue in the region in which the ratio of the distance between an edge surface of the electrode and an edge surface of one of the first interconnections positioned most adjacent to the electrode to the total thickness of the conductor and the electrode is less than the predetermined value unless the second or other interconnections (such as, a third interconnection, a fourth interconnection) is not positioned directly under the region. This ensures that the shirt-circuit fault between the electrode and the first interconnections is prevented. At the same time, even when the first interconnections are densely positioned and the each pitch of the first interconnections is made smaller, the metal layer is etched without leaving the residue in the region.

While there have been described the embodiments in accordance with the present invention, the present invention is not limited to the aforementioned embodiments and various modifications are possible.

The WLCSP according to the aforementioned embodiments is appropriate to an application having a frequency of several hundred MHz to several GHz, such as a mobile device or a local area network.

What is claimed is:

1. A semiconductor device, comprising:
an external terminal;
a plurality of first interconnections positioned below the external terminal;
an electrode positioned at the same level as the electrode;
a conductor electrically connecting the external terminal and the electrode; and
a second interconnection positioned below the first interconnections and the electrode, wherein
the device has a region where the shortest distance between an edge surface of the electrode and an edge surface of one of the first interconnection positioned most adjacent to the electrode is less than 0.11 times the total thicknesses of the conductor and the electrode, and
the second terminal is positioned at a position different from that of the region in a thickness direction of the device.

2. The semiconductor device of claim 1, further comprising
multiple ones of the external terminal, the conductor, the electrode, and the region, wherein
each of the multiple ones of the external terminal is connected to the one electrode through the one conductor, and
the second interconnection is positioned at position different from all of the region in the thickness direction of the device.

3. The semiconductor device of claim 1, further comprising
a third interconnection positioned below the second interconnection, wherein
the third interconnection is positioned at a position different from that of the region in the thickness direction of the device.

4. The semiconductor device of claim 3, further comprising
multiple ones of the external terminal, the conductor, the electrode, and the region, wherein
each of the multiple ones of the external terminal is connected to the one electrode through the one conductor, and
the third interconnection is positioned at position different from all of the region in the thickness direction of the device.

5. The semiconductor device of claim 1, wherein
each of the first and the second interconnections includes Cu and has a thickness of 1.5 μm or more.

6. The semiconductor device of claim 3, wherein
the third interconnection includes Al and has a thickness of 1.5 μm or more.
